(19) United States
(12) Patent Application Publication
(10) Pub. No.: US 2005/0263869 A1
(43) Pub. Date: Dec. 1, 2005

(54) Semiconductor device and manufacturing process therefor

(75) Inventors: Naotaka Tanaka, Kasumigaura-shi (JP); Norio Nakazato, Kashiwa-shi (JP); Takahiro Naito, Kodaira-shi (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignees: Renesas Technology Corp., Tokyo (JP); Hitachi, Ltd., Tokyo (JP)

(21) Appl. No.: 11/138,936

(22) Filed: May 25, 2005

(30) Foreign Application Priority Data
May 25, 2004 (JP) 2004-155143

(51) Int. Cl. H01L 23/495

(52) U.S. Cl. 257/686

(57) ABSTRACT

To provide a very-low-cost and short-TAT connection structure superior in connection reliability in accordance with a method for three-dimensionally connecting a plurality of semiconductor chips at a shortest wiring length by using a through-hole electrode in order to realize a compact, high-density, and high-function semiconductor system. The back of a semiconductor chip is decreased in thickness up to a predetermined thickness through back-grinding, a hole reaching a surface-layer electrode is formed at a back position corresponding to a device-side external electrode portion through dry etching, a metallic deposit is applied to the sidewall of the hole and the circumference of the back of the hole, a metallic bump (protruded electrode) of another semiconductor chip laminated on the upper side is deformation-injected into the through-hole by compression bonding, and the metallic bump is geometrically caulked and electrically connected to the inside of a through-hole formed in an LSI chip. It is possible to realize a unique connection structure having a high reliability in accordance with the caulking action using the plastic flow of a metallic bump in a very-low-cost short-TAT process and provide a three-dimensional inter-chip connection structure having a high practicability.

### BACKGROUND OF THE INVENTION

The present invention relates to a semiconductor device having a plurality of semiconductor chips three-dimensionally laminated.

### PRIOR ART

In recent years, a system-in-package technique has been noticed which mounts a plurality of semiconductor chips on which integrated circuits are mounted at a high density to realize an advanced-function system in a short period and various mounting structures are proposed from various companies. Particularly, development of a laminated package which is able to three-dimensionally laminate a plurality of semiconductor chips and realize great downsizing.

Because wire bonding is mainly used for electrical connection between a semiconductor chip and a mounting substrate, it is necessary to make an upper-stage semiconductor chip to be laminated smaller than a lower-stage semiconductor chip to be laminated. When laminating semiconductor chips having the same size, it is necessary to secure a wire bonding area by using a structure holding a spacer. Because wire bonding connection has a high pulling versatility, it is very effective method in order to realize the electrical connection between a plurality of existing semiconductor chips in a short TAT (Turn Around Time).

However, in the case of the wire bonding connection, it is necessary to once drop all wirings from a plurality of chip electrodes on a mounting substrate and then perform re-wiring on one-hand chip. Therefore, there are a problem that the wiring length between chips becomes very long and a problem that the wiring density of the mounting substrate becomes very high. Thereby, a problem occurs that the inductance between chips increases and high-speed transmission becomes difficult and moreover, a problem may occur that an yield is deteriorated due to high density of the mounting substrate and a substrate cost is increased.

A method for connecting chips not through a mounting substrate is proposed for these problems in wire bonding connection. For example, JP-A-2001-217385 discloses a method for making it possible to connect laminated upper and lower chips by a package structure obtained by attaching a tape-carrier-like wiring tape to the upside, downside, and one side of a semiconductor chip setting an external connection terminal to these sides. Though this is a conventional package laminating method for individually packaging the chips and connecting them by an external electrode, this realizes three-dimensional lamination at the same level as a chip size in accordance with the contrivance of a packaging method. However, because of the laminating structure of individual packages, there are problems that the wiring length between chips becomes long and the versatility when mounting and laminating chips having different chip sizes is restricted.

However, JP-A-11-251316 and JP-A-2000-260934 disclose a method for forming an electrode penetrating the inside of a chip and connecting upper and lower chips. JP-A-11-251316 provides a semiconductor chip having a through-hole electrode greatly simplifying a fabrication process by forming a copper through-hole electrode at the same time in a process for fabricating a device constituted of a copper wiring. JP-A-2000-260934 provides a method for three-dimensionally connecting chips by forming an electrode obtained by embedding solder or low-melting-point metal in a through-hole portion formed in a chip through the electrolytic or electroless plating method on the upside and downsize of a chip, laminating chips, then heating the chips, and melt-joining an embedded electrode.
[Patent Document 1] JP-A-2001-217385
[Patent Document 2] JP-A-11-251316
[Patent Document 3] JP-A-2000-260934

### BRIEF SUMMARY OF THE INVENTION

As described above, a method using wire bonding is the mainstream as a method for three-dimensionally laminating and packaging a plurality of semiconductor chips. It is estimated in future that a wiring length becomes a bottleneck for high-speed transmission and securing of a bonding area becomes a bottleneck for decrease in size and thickness. As a method substituting for it, a method for three-dimensionally connecting chips by shortest wiring using a through-hole electrode is proposed. Because the process for forming a through-hole electrode is a new process which is not included in a conventional wafer process or mounting process, it is necessary that a process load is small, a short TAT is used, a connection method is easy, and a conventional reliability can be secured.

A method for simultaneously forming a copper through-hole electrode in the device fabrication process disclosed in JP-A-11-251316 is effective to decrease a process load. However, because the difference between reference dimensions of the device fabrication process and the mounting process is two digits or more, forming a through-hole electrode assuming inter-chip connection according to the mounting process simultaneously in the device fabrication process may decrease the yield in device fabrication and TAT.

Moreover, a method for forming a bump electrode at a through-hole portion in a chip through the plating growth disclosed in JP-A-2000-260934 has problems that the plating growth normally requires a lot of time (several hours or more) and it is technically difficult to perform uniform growth including a through-hole portion.

The outline of a typical invention among inventions disclosed in this application is briefly described below.

A method for realizing inter-chip connection using a through-hole electrode formed in a semiconductor chip is realized at a short TAT and low cost by decreasing the back of an LSI chip (semiconductor chip) up to a predetermined thickness through back grinding, forming a hole reaching up to surface-layer-side electrode at a back position corresponding to a device-side external electrode portion through dry etching, forming a metallic deposit on the sidewall and the circumference of the back of the hole, deformation-filling a metallic bump formed on the electrode of another LSI chip to be laminated on the upper stage side by compression bonding, geometrically caulking and electrically connecting the metallic bump in a through-hole formed in the LSI chip, and finally injecting an adhesive such as UNDER-FILL into the gap between upper and lower LSI chips and curing the adhesive.

Features of this connection method are not to fill the inside of a hole formed for a through-hole electrode in an LSI chip by electrolytic plating but to make good use of the sidewall and back-side electrode portion of a through-hole as a connection electrode. Advantages and features of this connection method are described below.

(1) Because of not filling the inside of a hole by electrolytic plating but only forming a metallic deposit of a thin film on the back-side electrode portion including sidewall, a plating filling step requiring a lot of time and a CMP (Chemical Mechanical Polishing) step after the plating step are unnecessary and fabrication can be made in a short-TAT and low-cost process.

(2) Metallic bumps injected into a through-hole electrode hole by plastic flow at the time of compression bonding are kept in a stable junction state with a plating electrode portion by its spring back action Moreover, because the metallic bump has a large linear expansion coefficient compared to Si, a caulking state due to a thermal expansion difference is formed also at the time of reflow heating and a stable connection state is kept also at a high temperature.

(3) It is possible to correspond to a process for connection between chips by a method same as the conventional compression bonding method using gold stud bumps.

Advantages obtained from a typical invention among inventions disclosed in this application are briefly described below.

Three-dimensionally connecting a plurality of LSI chips at a minimum wiring length is made possible and the following advantages can be obtained.

(1) Because the inside of a through-hole electrode is not filled with electrolytic plating but metallic deposit of a thin film is only formed on the back-side electrode portion including a sidewall, a plating filling step requiring a lot of time and a CMP (Chemical Mechanical Polishing) step after the plating filling step are unnecessary and fabrication can be made at a short TAT and a low cost.

(2) Metallic bumps injected into a through-hole electrode hole by plastic flow at the time of compression bonding are kept in a stable connection state with a plating electrode portion in the through-hole electrode hole. Moreover, because the metallic bump has a large linear expansion coefficient compared to Si, a caulking state by a thermal expansion difference is formed also at the time of reflow heating and a stable connection state is kept.

(3) It is possible to correspond to a process for connection between chips with a method same as the conventional compression bonding method using gold stud bumps. That is, it is possible to realize a unique connection structure having a high reliability by the caulking action using a plastic flow deformation of metallic bumps in a very-low-cost and short-TAT process and provide a three-dimensional inter-chip connection structure having a high practicability.

Other objects, features and advantages of the invention will become apparent from the following description of the embodiments of the invention taken in conjunction with the accompanying drawings.

### BRIEF DESCRIPTION OF THE SEVERAL VIEWS OF THE DRAWING

FIG. 1 is a schematic sectional view showing a schematic configuration of a semiconductor device of embodiment 1 of the present invention;

FIG. 2 is a schematic sectional view obtained by enlarging a part of the semiconductor device shown in FIG. 1;

FIG. 3 is a schematic sectional view showing a schematic configuration of the semiconductor chip in FIG. 1;

FIG. 4 is a schematic sectional view obtained by enlarging a part of the semiconductor chip in FIG. 3;

FIGS. 5A and 5B are illustrations for explaining fabrication of a semiconductor chip in fabrication of the semiconductor device of the embodiment 1 of the present invention, in which FIG. 5A is a schematic top view and FIG. 5B is a schematic sectional view;

FIGS. 6A and 6B are schematic sectional views for explaining fabrication of a semiconductor chip in fabrication of the semiconductor device of the embodiment 1 of the present invention;

FIGS. 7A and 7B are schematic sectional views for explaining fabrication of a semiconductor chip in fabrication of the semiconductor device of the embodiment 1 of the present invention;

FIGS. 8A and 8B are schematic sectional views for explaining fabrication of a semiconductor chip in fabrication of the semiconductor device of the embodiment 1 of the present invention;

FIGS. 9A and 9B are schematic sectional views for explaining fabrication of a semiconductor chip in fabrication of the semiconductor device of the embodiment 1 of the present invention;

FIGS. 10A and 10B are schematic sectional views for explaining fabrication of a semiconductor chip in fabrication of the semiconductor device of the embodiment 1 of the present invention;

FIGS. 11A and 11B are schematic sectional views for explaining fabrication of the semiconductor device of the embodiment 1 of the present invention;

FIG. 12 is a schematic sectional view for explaining fabrication of the semiconductor device of the embodiment 1 of the present invention;

FIG. 13 is a schematic sectional view for explaining fabrication of the semiconductor device of the embodiment 1 of the present invention;

FIG. 14 is a schematic sectional view for explaining fabrication of the semiconductor device of the embodiment 1 of the present invention;

FIG. 15 is a schematic sectional view of a semiconductor chip which is a modification of the embodiment 1 of the present invention;

FIGS. 16A and 16B are schematic sectional views for explaining fabrication of a semiconductor device of embodiment 2 of the present invention;

FIG. 17 is a schematic sectional view for explaining fabrication of the semiconductor device of the embodiment 2 of the present invention;

FIG. 18 is a schematic sectional view for explaining fabrication of a semiconductor device of embodiment 3 of the present invention;

FIG. 19 is a schematic sectional view showing a schematic configuration of a semiconductor device of embodiment 4 of the present invention;

FIG. 20 is a schematic sectional view showing a schematic configuration of a semiconductor device of embodiment 5 of the present invention;

FIG. 21 is a schematic sectional view showing a schematic configuration of a semiconductor device of embodiment 6 of the present invention;

FIG. 22 is a schematic sectional view showing a schematic configuration of a semiconductor device of embodiment 7 of the present invention;

FIG. 23 is a schematic sectional view showing a schematic configuration of a semiconductor device of embodiment 8 of the present invention;

FIG. 24 is a schematic sectional view showing a schematic configuration of a semiconductor device of embodiment 9 of the present invention;

FIG. 25 is a schematic sectional view for explaining fabrication of a semiconductor device of embodiment 10 of the present invention;

FIG. 26 is a schematic sectional view for explaining fabrication of a semiconductor device of embodiment 11 of the present invention;

FIG. 27 is a schematic sectional view showing a bump connection structure between semiconductor chips of embodiment 12 of the present invention; and

FIG. 28 is a schematic sectional view for explaining fabrication of a semiconductor device of embodiment 13 of the present invention.

### DETAILED DESCRIPTION OF THE INVENTION

Embodiments of the present invention are described below in detail by referring to the accompanying drawings. In all drawings for explaining embodiments of the present invention, components having the same function are provided with the same symbol and their repetitive description is omitted.

### Embodiment 1

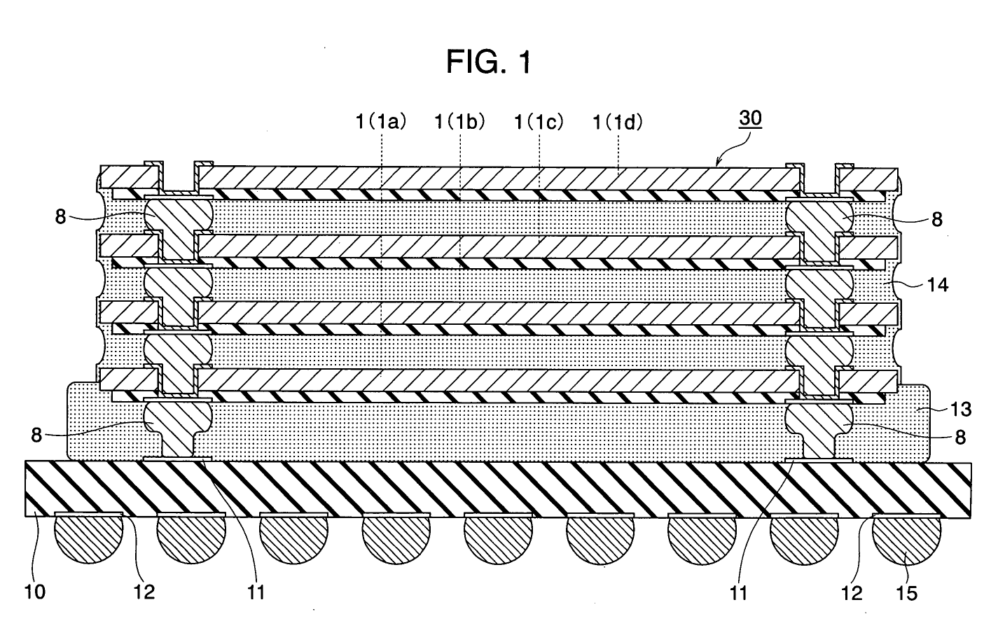

FIGS. 1 to 14 are illustrations of a semiconductor device of embodiment 1 of the present invention.

FIG. 1 is a schematic sectional view showing a schematic configuration of the semiconductor device.

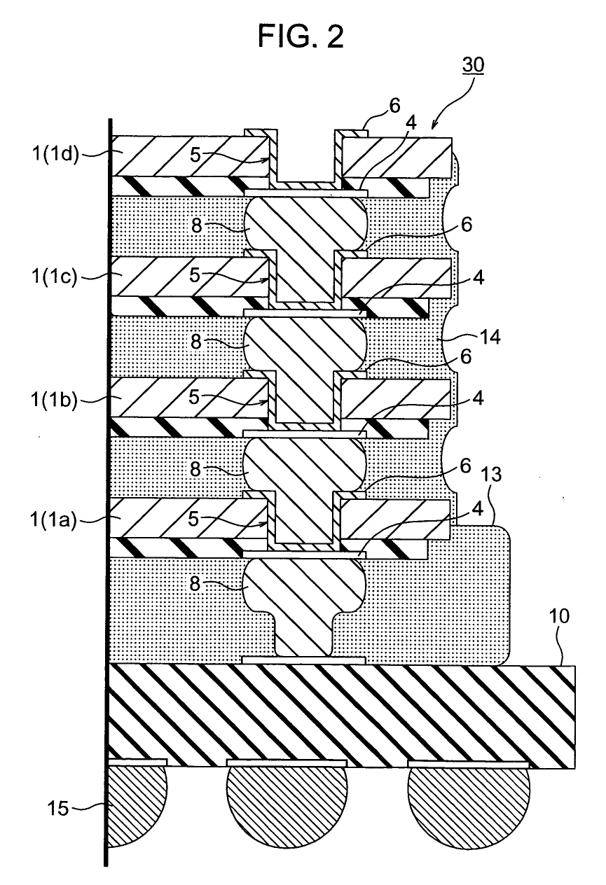

FIG. 2 is a schematic sectional view obtained by enlarging a part of FIG. 1.

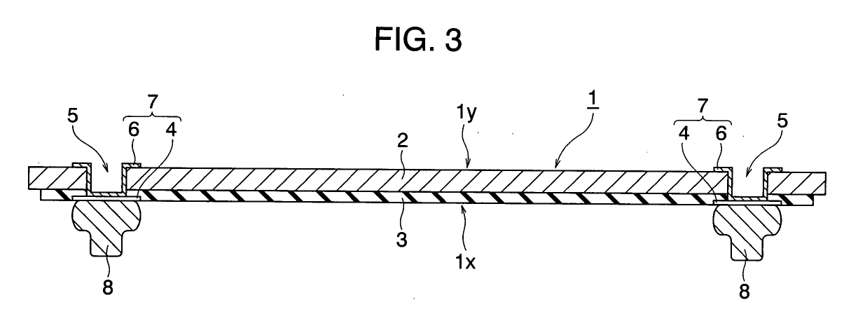

FIG. 3 is a schematic sectional view showing a schematic configuration of the semiconductor chip in FIG. 1.

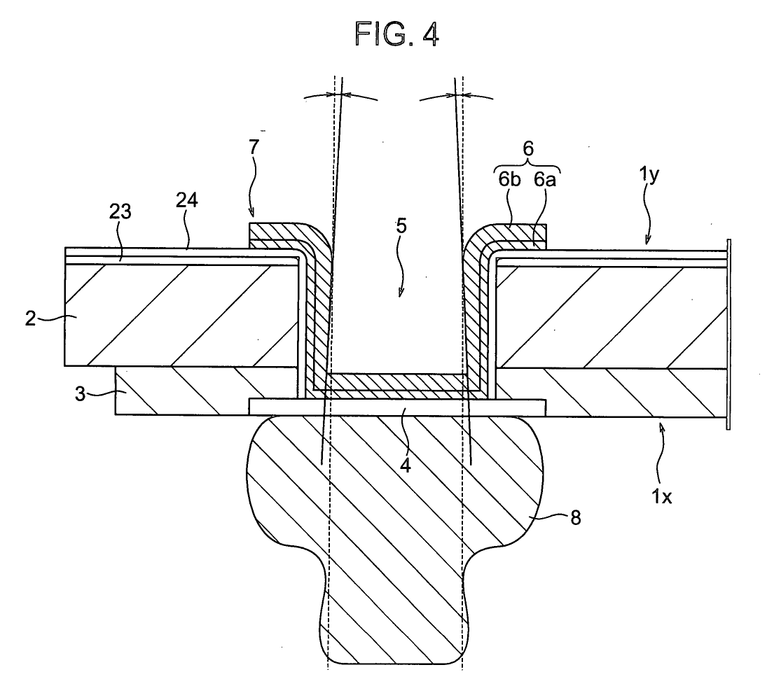

FIG. 4 is a schematic sectional view obtained by enlarging a part of FIG. 3.

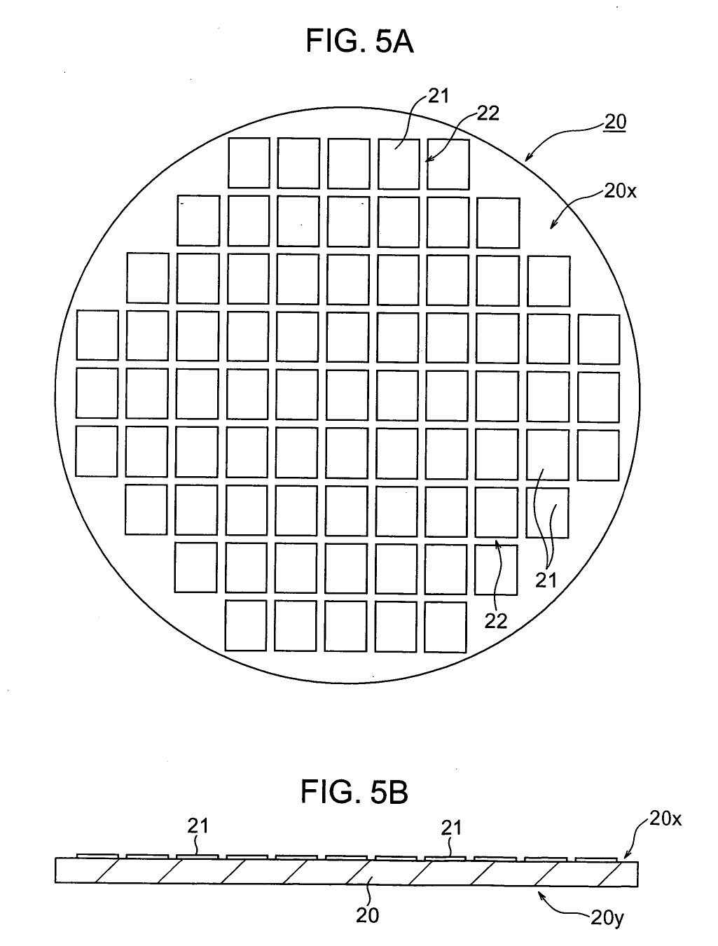

FIGS. 5 to 10 are illustrations for explaining fabrication of a semiconductor chip in fabrication of a semiconductor device (A is a schematic top view and B is a schematic sectional view).

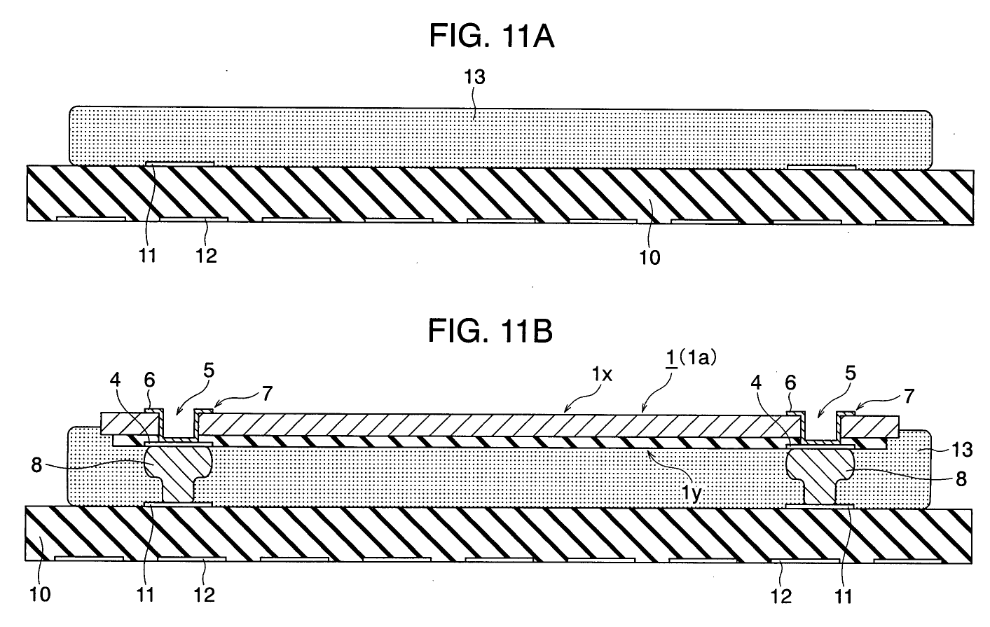

FIGS. 11 to 14 are schematic sectional views for explaining an assembling process in fabrication of a semiconductor device.

As shown in FIG. 1, the semiconductor device of this embodiment 1 has a package structure having a chip laminated body 30 constituted of a plurality of semiconductor chips 1 stereoscopically laminated on the principal plane of a wiring board 10. This embodiment 1 is not restricted to the above structure. For example, four semiconductor chips 1 ((1a), (1b), (1c), and (1d)) are stereoscopically laminated.

In the case of the wiring board 10, a flat shape intersecting with its plate thickness direction is square. In the case of this embodiment, the flat shape is rectangular. The wiring board 10 is not restricted to the rectangular shape. For example, the wiring board 10 is constituted of a resin substrate obtained by impregnating epoxy or polyimide resin in glass fiber and a plurality of electrode pads (lands) 11 constituted of parts of a plurality of wirings are arranged on the principal plane of the wiring board 10 and a plurality of electrode pads (lands) 12 constituted of parts of a plurality of wirings are arranged on the back at the opposite side to the principal plane. The electrode pads 11 are electrically connected with the electrode pads 12 through a through-hole formed on the wiring board 10.

A solder bump 15 is electrically and mechanically connected to each of the electrode pads 12 as an external connection terminal (external electrode).

Though the semiconductor chip 1 is not illustrated in detail, the flat shape intersecting with the thickness direction is square. In the case of this embodiment, the flat shape is rectangular.

The semiconductor chip 1 is not restricted to the rectangular shape. As shown in FIG. 3, the semiconductor chip 1 is constituted by including a semiconductor substrate 2, a plurality of transistor devices formed on the principal plane of the semiconductor substrate 2, and a thin-film laminated body (multilayer wiring layer) 3 obtained by stacking a plurality of insulating layers and a plurality of wiring layers. The semiconductor substrate 2 uses, for example, a single-crystalline silicon substrate. The insulating layer of the thin-film laminated body 3 uses, for example, a silicon oxide film and the wiring layer uses a metallic film made of aluminum (Al), aluminum alloy, copper (Cu), or copper alloy.

The semiconductor chip 1 has the principal plane (circuit forming plane or device forming plane) 1x and the back 1y located at the opposite side each other and an integrated circuit is formed on the principal plane 1x of the semiconductor chip 1. For example, an EEPROM (Electrically Erasable Programmable Read Only Memory referred to as flash memory which is one of memory circuits) is formed as the integrated circuit. The integrated circuit is mainly constituted of a transistor device formed on the principal plane of the semiconductor substrate 1 and a wiring formed on a thin-film lamination layer 2.

A plurality of electrode pads (bonding pads) 4 are arranged on the principal plane 1x of the semiconductor chip 1. In the case of this embodiment 1, the electrode pads 4 are arranged along two sides located at the mutually opposite side of the principal plane 1x of the semiconductor chip 1. The electrode pads 4 are formed on the wiring layer which is the highest layer in the thin-film laminated body 3 of the semiconductor chip 1 and exposed by bonding openings formed correspondingly to the electrode pads 4 formed on the insulting layer which is the highest layer in the thin-film laminated body 3.

The semiconductor chip 1 has through-holes 5 formed correspondingly to the electrode pads 4 and moreover has a plurality of through-hole electrodes 7. The through-holes 5 are constituted so as to reach the electrode pads 4 from the back 1y of the semiconductor chip 1 through the semiconductor substrate 21 and multilayer thin-film body 3. The through-hole electrodes 7 are respectively constituted so as to have the electrode pads 4 formed on the principal plane 1x of the semiconductor chip 1 and an electrode 6 formed on the inner wall surface of the through-hole 5 and electrically connected with the electrode pad 4. The electrode 6 of this embodiment 1 is extended to the back 1y of the semiconductor chip 1 and formed so as to cover the back of the electrode pad 4. The electrode 6 is formed into a concave shape along the inner wall surface of the penetration hole 5.

A stud bump 8 made of Au is set to each electrode pad 4 as a protruded electrode (conductive bump) protruded from the principal plane 1x of the semiconductor chip 1 and electrically and mechanically connected to each electrode pad 4.

As shown in FIGS. 1 and 2, in the case of the chip laminated body 30, the principal plane 1x of the semiconductor chip 1 (1a) at the lowest stage is faced with the principal plane of the wiring board 10 and bonded and fixed to the principal plane of the wiring board 10 through an adhesive 13 between the principal plane 1× and the principal plane of the wiring board 10. The adhesive 13 uses a sheet-like anisotropic conductive resin (ACF: Anisotropic Conductive Film) obtained by mixing a lot of conductive particles in an epoxy thermosetting insulating resin.

The stud bump 8 of the lowest-stage semiconductor chip (1a) is compression-bonded to the electrode pad 11 of the wiring board 10 by the heat shrinkage force (shrinkage force generated when returned from a heated state to ordinal temperature) or thermosetting insulating shrinkage force (shrinkage force generated when thermosetting insulating resin is cured) of the adhesive 13 and electrically connected with the electrode pad 11.

In the case of two semiconductor chips faced each other of the chip laminated body 30 (1a and 1b, 1b and 1c, and 1c and 1d), a part of the stud bump 8 of the semiconductor chip 1 located at the upper stage is inserted into the through-hole 5 (concave portion of the electrode 6) of the lower-stage semiconductor chip 1 and the stud bump 8 is electrically connected with the electrode pad 4 of the lower-stage semiconductor chip 1. A part of the stud bump 8 is compression-bonded into the through-hole 5 (concave portion of the electrode 6) due to deformation followed by plastic flow. In the case of this embodiment 1, the through-hole 5 of the lower-stage semiconductor chip 1 is filled with the stud bump 8 of the upper-stage semiconductor chip 1.

The electrode 6 of each semiconductor chip 1 is electrically insulated from a semiconductor substrate 2 by insulating films (23 and 24) formed on the back 1y of the semiconductor chip 1 and an insulating film 24 formed along the inner wall surface of the through-hole 5.

An electrode 5 is not restricted to the above mentioned. For example, the electrode 5 is formed of a multilayer film including a seed layer 6a and a metallic deposit 6b from the bottom. The seed layer 6a is formed of a multilayer film (Ti/Cu) including a Ti film and a Cu film from the bottom and the metallic deposit 6b is formed of a multilayer film (Cu/Au) including a Cu film and an Au film.

The gap between semiconductor chips 1 is sealed by a sealing adhesive 14 such as UNDER-FILL, which holds a mechanical strength and is protected from an external environment.

This embodiment 1 shows an embodiment according to multistage lamination layer when the electrode arrangement (inter-chip connection position) and chip size of each semiconductor chip 1 are equivalent. For example, compact- and thin-type and large capacity are realized by a multistage lamination layer of, for example, a flash memory to assume an application as a large-capacity memory built in a multimedium card. Moreover, because a net between semiconductor chips 1 is closed by connection between the semiconductor chips 1, it is unnecessary to raise the wiring density of the wiring board 10 (mounting board) like the conventional wire bonding connection and it is possible to construct a large-capacity memory system by using an inexpensive subtraction-type two-layer substrate or the like.

Then, fabrication of the semiconductor device of this embodiment 1 is described below by referring to FIGS. 5 to 14. First, fabrication of the semiconductor chip 1 is described and then, assembling of a semiconductor device is described.

First, a semiconductor wafer 20 is prepared (refer to FIG. 5). The semiconductor wafer 20 uses a semiconductor wafer constituted made of single-crystalline silicon, for example.

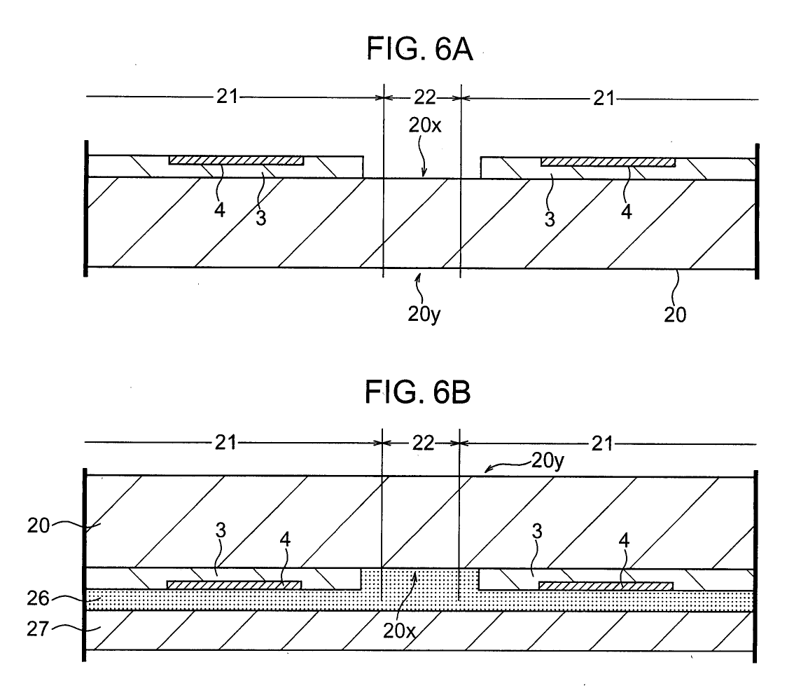

Then, as shown in FIGS. 5A and 5B and FIG. 6A, an integrated circuit (flash memory for this embodiment) and a plurality of chip forming regions 21 having a plurality of electrode pads 4 are formed on the principal plane (circuit forming face or device forming face) 20×of the semiconductor wafer 20 like a matrix. The chip forming regions 21 are comparted by a scribing region (scribing line, separation region, or dicing region) and arranged in a state in which the chip forming regions 21 are separated from each other. The chip forming regions 21 are formed by mainly forming a transistor device, the thin-film lamination body 3 (refer to FIG. 6A), and the electrode pad 4 on the principal plane 20x of the semiconductor wafer 20. The thin-film lamination body 3 is formed by stacking a plurality of insulating layers and a plurality of wiring layers on the principal plane 20x of the semiconductor wafer 20.

Then, as shown in FIG. 6B, the semiconductor wafer 20 is attached to a support substrate 27 constituted of, for example, a quartz glass substrate. The semiconductor wafer 20 is attached through a protective tape 26 so that the principal plane 20x of the semiconductor wafer 20 faces the support substrate 27. The protective tape 26 uses a protective tape having an adhesive layer (sticky layer) made of polyether amide-imide or epoxy ultraviolet curing resin, for example.

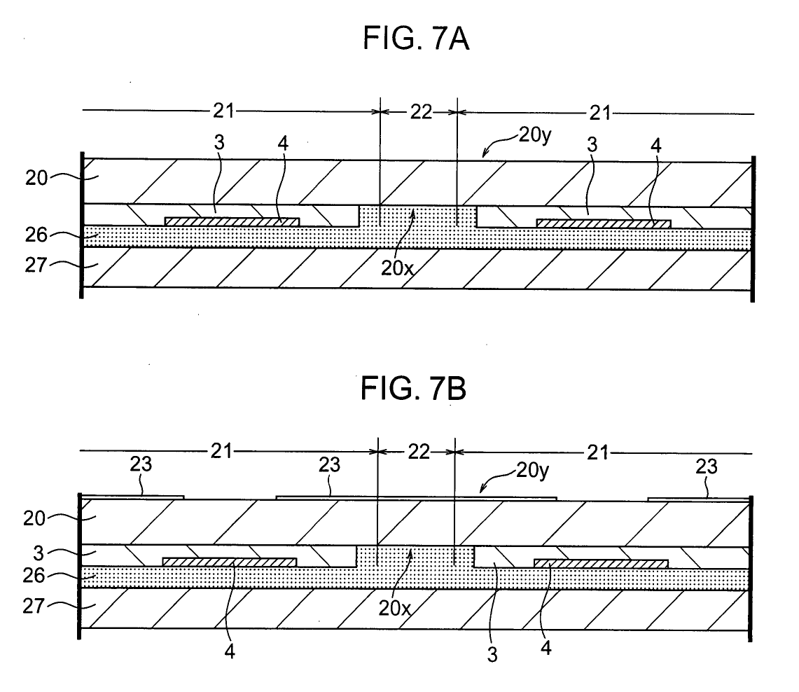

Then, back grinding is applied to the back 20y of the semiconductor wafer 20 to decrease the semiconductor wafer 20 in thickness as shown in FIG. 7A. Because the connection stability and TAT in the subsequent process are improved by further decreasing the wafer 20 in thickness, a thickness of 50 μm or less, preferably 30 μm or less is used as a proper thickness. When the flatness of the working face of the back of the wafer influences the subsequent fabrication process, the working face is flattened by applying proper dry polishing or wet etching.

Then, an insulating film 23 made of a silicon oxide film is formed on the back 20y of the semiconductor wafer 20 and then, the insulating film 23 is patterned by using the photolithography technique to form the insulating film 23 on which a through-hole forming region is opened as shown in FIG. 7B.

Then, the back 20y of the semiconductor wafer 20 exposed from the insulating film 23 is etched through anisotropic etching such as RIE (Reactive Ion Etching) to form a through-hole 5 reaching the electrode pad 4 from the back 20y of the semiconductor wafer 20 (back 2y of the semiconductor substrate 2).

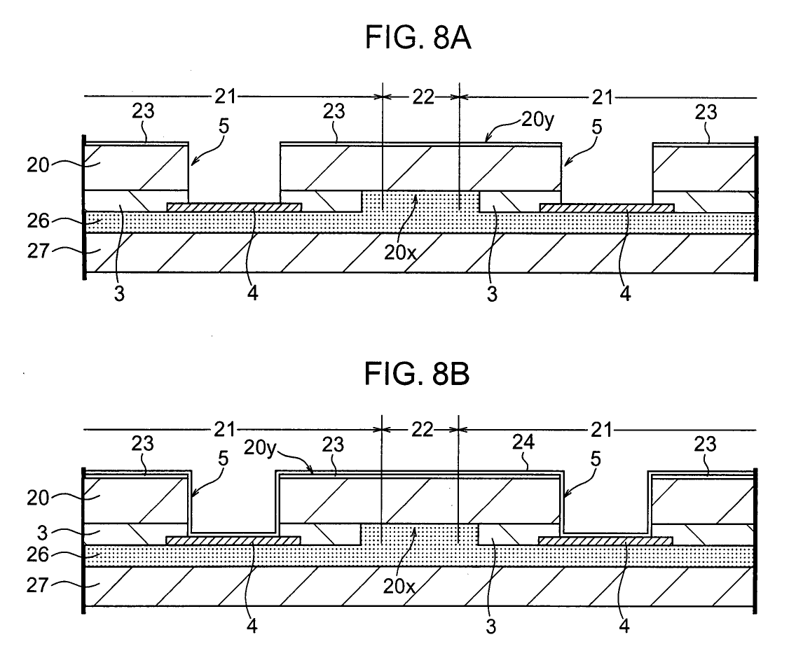

Then, as shown in FIG. 8B, an insulating film 24 made of a silicon oxide film is formed on the entire surface of the back 20y of the semiconductor wafer 20 including the inside of the through-hole 5 through plasma CVD (Chemical Vapor Deposition). The insulating film 24 is formed so as to cover the through-hole 5 and electrode pad 4 along the inner wall surface of the through-hole 5 and the back of the electrode pad 4. It is allowed to remove the insulating film 23.

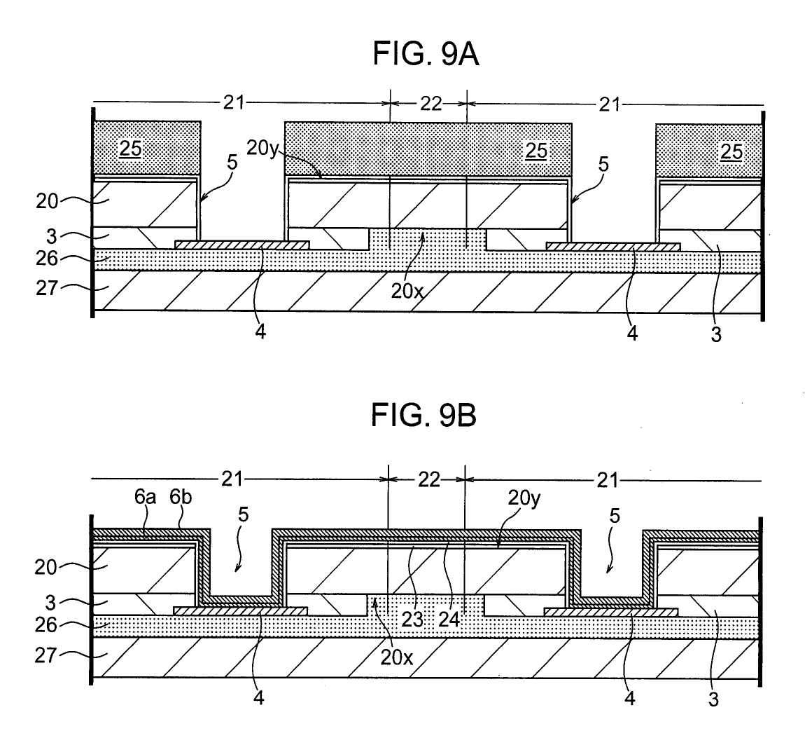

Then, as shown in FIG. 9A, a mask 25 made of, for example, a photoresist film is formed on the back 20y of the semiconductor wafer 20. The mask 25 has an opening on the through-hole 5 and the inside diameter of the opening is smaller than the inside diameter of the through-hole 5 so that at least the insulating film 24 on the inner wall surface of the through-hole 5 is hidden.

Then, the mask 25 is used as an etching mask and the insulating film 25 is etched to selectively remove the insulating film 24 covering the back of the electrode pad 4 as shown in FIG. 9A.

Then, the mask 25 is removed to successively form the seed layer 6a and metallic deposit 6b on the entire surface of the back 20y of the semiconductor wafer 20 including the inside of the through-hole 5. The seed layer 6a is formed of a multilayer film including a Ti film and Cu film from the bottom in order to secure the adhesiveness between the insulating film 24 and the electrode pad 4 and these films are formed by, for example, the sputtering method. The metallic deposit 6b is formed of a multilayer film including a Cu layer and Au film from the bottom, for example, and these films are formed through the electrolytic plating method. Combinations of Cu and Au and Ti and Au are considered as types of the metallic deposit 6b. However, it is preferable that at least the metallic deposit which is the outermost layer is made of Au.

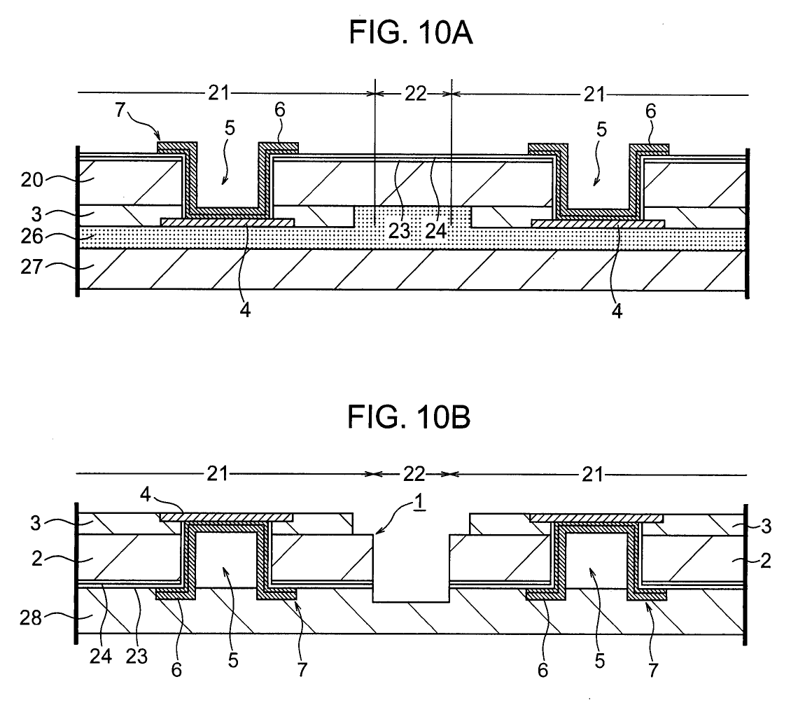

Then, the metallic deposit 6b and seed layer 6a are successively patterned to form a concave electrode 6 formed along the inner wall surface of the through-hole 5, electrically connected with the electrode pad 4, and insulated from the semiconductor wafer 20 (semiconductor substrate 2) as shown in FIG. 10A. According to this step, a through-hole electrode 7 having the electrode pad 4 and electrode 6 is formed.

Then, the semiconductor wafer 20 is removed from the support substrate 27 and then the semiconductor wafer 20 is attached to a dicing tape 28 (refer to FIG. 10B). The semiconductor wafer 20 is attached so that the principal plane of the dicing tape 28 at the sticky layer side faces the back 20y of the semiconductor wafer 20.

Then, the semiconductor wafer 20 is diced along the scribing region 22 of the semiconductor wafer 20 to divide the semiconductor wafer 20 into a plurality of semiconductor chips 1 as shown in FIG. 10B.

Thereafter by forming, for example, the stud bump 8 on the electrode pad 4 of the semiconductor chip 1 as a protruded electrode, the semiconductor chip 1 shown in FIG. 3 is formed. The stud bump 8 is formed by melting the front end of an Au wire to form a ball, thereafter thermocompression-bonding the ball to the electrode pad 4 of the semiconductor chip 1 while applying ultrasonic vibrations, then disconnecting the portion of the ball from the Au wire. It is preferable that the stud bump 8 is formed of a low-rigidity metallic bump.

Then, assembling of the semiconductor device of this embodiment 1 is described.

First, as shown in FIG. 11A, for example, ACF (hereafter may be referred to as ACF (13)) is attached to the chip mounting region of the principal plane of the wiring board 10 as the adhesive 13.

Then, the lowest-stage semiconductor chip 1 (1a) is positioned to the ACF (13) and then, the semiconductor chip 1 (1a) is compression-bonded to the principal plane of the wiring board 10 as shown in FIG. 11B while heating the wiring board 10 and semiconductor chip 1 (1a). Compression-bonding of the semiconductor chip 1 (1a) is performed until the thermosetting resin of the ACF (13) is cured. In accordance with this step, the lowest-stage semiconductor chip 1 (1a) is bonded to the principal plane of the wiring board 10 by the resin of the ACF (13) and the stud bump 8 of the semiconductor chip 1 (1a) is electrically connected with the electrode pad 11 of the wiring board 10 through conductive particles of the ACF (13).

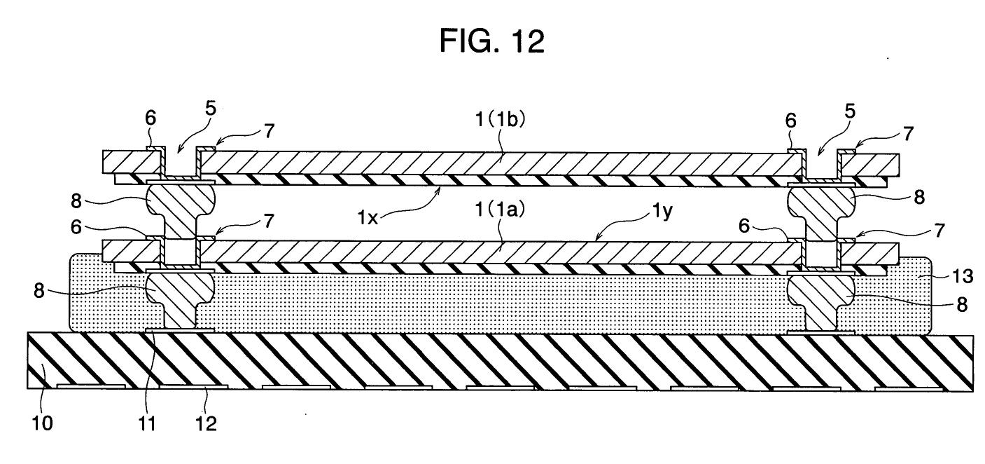

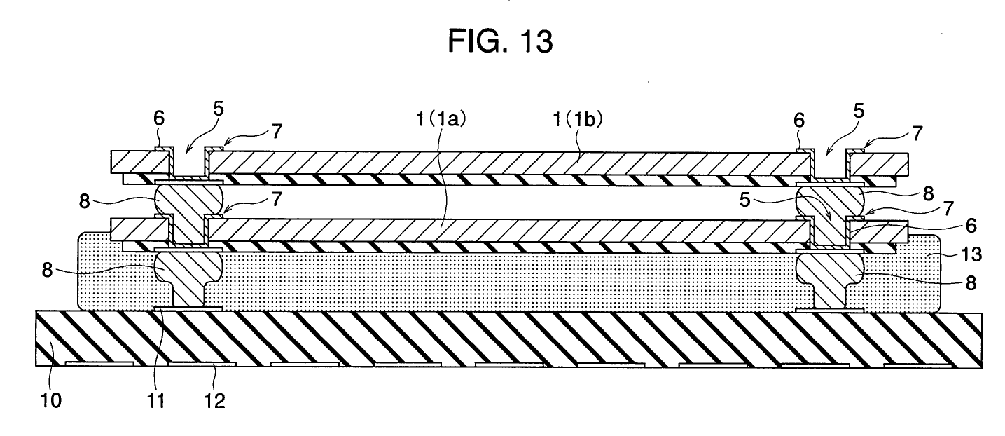

Then, as shown in FIG. 12, the second semiconductor chip 1 (1b) is positioned on the lowest-stage semiconductor chip 1 (1a) so that the stud bump 8 of the second semiconductor chip 1 (1b) is located on the through-hole electrode 7 of the lowest-stage semiconductor chip 1 (1a) and then, the second semiconductor chip 1 (1b) is compression-bonded as shown in FIG. 13. In this step, a part of the stud bump 8 of the second semiconductor chip 1 (1b) is compression-bonded and injected into the through-hole 5 (concave portion of the electrode 6) of the lowest-stage semiconductor chip 1 (1a) in accordance with the deformation followed by plastic flow. The through-hole 5 of the lowest-stage semiconductor chip 1 (1a) is packed by the stud bump 8 of the second semiconductor chip 1 (1b) through the electrode 5.

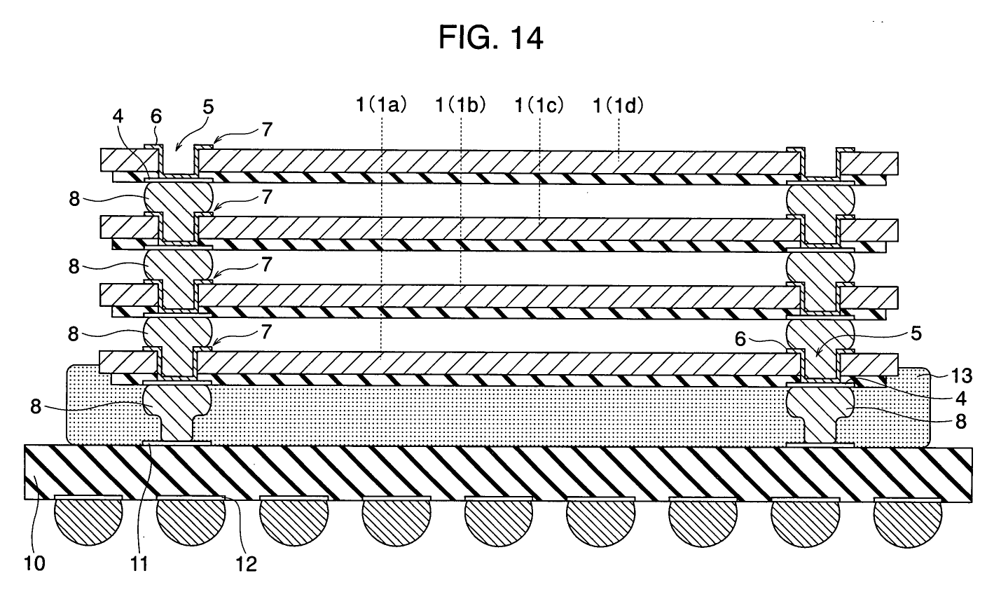

Thereafter, by compression-bonding third and fourth semiconductor chips 1 (1c and 1d) similarly to the second semiconductor chip 1 (1b), a chip lamination body 30 having four semiconductor chips 1 stereoscopically laminated on the principal plane of the wiring board 10 is formed as shown in FIG. 14.

Thereafter, by injecting the sealing resin 14 between the semiconductor chips 1 and then, forming the solder bump 15 on the electrode pad 4 of the wiring board 10, the semiconductor device shown in FIG. 1 is almost finished.

It is allowed to form the stud bump 8 at a wafer level before the step (back grinding step) in FIG. 7A. In this case, it is necessary to bond and support the device side under a wafer state provided with a bump by a tape or the like. Because dicing into each chip size can be performed without exfoliating a support tape, it is possible simplify the fabrication process.

In the fabrication process flow shown in

FIGS. 5 to 10, when forming a plurality of through-holes 5 on the back of a wafer through dry etching, as shown in FIG. 4, sidewall surfaces of the holes are worked into shapes in which sidewall surfaces of the holes tilt by 0° to 5° outward from the vertical normal line. That is, the through-holes 5 are formed in shapes in which inside diameters are equal or increase for the depth direction of the holes. Thereby, stud bumps 8 formed on the semiconductor chip 1 are injected into the holes due to plastic flow deformation at the time of compression bonding and a connection structure forming a geometric caulking state is realized. The edge portion of the back-side entrance of a through-hole portion is not formed into a right angle but it is preferably formed into an R shape or chamfered shape as illustrated so that a working resist film is continuously uniformly applied in the etching step of the metallic deposit shown in FIG. 10A. In the case of cross sections of inner walls of the holes, the insulating film 24 is formed on the silicon working plane and the seed layer 6a and the metallic deposit 6b by electrolytic plating are formed on the insulating film 24. The contact region between the electrode (through-hole electrode portion) 6 and the electrode pad (device-side electrode portion) 4 are electrically connected each other through the seed layer (Ti/Cu) 6a in order to secure the adhesiveness. Moreover, the back side of a wafer is protected by an another insulating film according to necessity. Also, it is preferable to form the inside of the concave portion of the electrode 6 into a shape tilting outward by 0° to 5° (bottom inside diameter>upside inside diameter).

Thus, according to this embodiment 1, the following advantages can be obtained.

(1) The inside of a through-hole is not plating-filled through electrolytic plating but a thin-film metallic deposit is only formed on the back-side electrode portion including sidewall. Therefore, the plating filling step requiring a lot of time or subsequent CMP (Chemical Mechanical Polishing) step is unnecessary and fabrication can be made in a short-TAT and low-cost process.

(2) A stud bump injected into a through-hole electrode hole by plastic flow at the time of compression bonding is kept in a stable connection state with the plating electrode portion in a through-hole electrode hole in accordance with the spring back action of the stud bump. Moreover, because a metallic bump has a large linear expansion coefficient compared to Si, a caulking state by thermal expansion difference is formed also at the time of reflow heating and a stable connection state is kept.

(3) It is possible to correspond to a process for connection between chips by the same method as the conventional compression bonding method using a gold stud bump.

That is, it is possible to realize a high-reliability unique inter-chip connection structure in a very-low-cost and short-TAT process and by a caulking action using the plastic flow deformation of a metallic bump and provide a high-practicability three-dimensional inter-chip connection structure.

For this embodiment 1, an example is described in which a stud bump is used as a protruded electrode. However, also when using a plated bump, it is possible to apply the present invention. Also when using the plated bump, it is preferable that the bum is formed of a low-rigidity metallic bump.

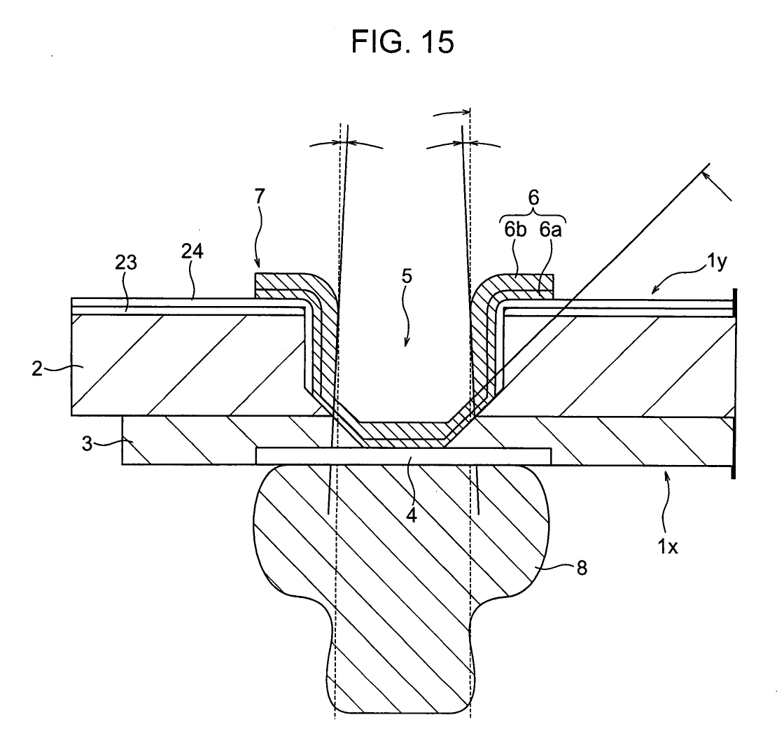

FIG. 15 is a schematic sectional view of a semiconductor chip showing a modification of this embodiment 1.

As shown in FIG. 15, it is the same as the case of FIG. 4 that the sidewall surface of the through-hole 5 is worked into a shape tilting outward from 0° to 5° from a vertical line. However, from the middle in the depth direction, the sidewall surface is worked into a shape tilting inward from 30° to 60° from a vertical line. That is, the sidewall surface is worked into a shape in which the inside diameter is equal or increases up to the middle in the depth direction of the hole and from the middle in the depth direction, a plurality of holes are formed in shapes in which inside diameters are decreased. Thereby, the contact region with the electrode pad (device-side external electrode portion) 4 becomes small and thus, it is possible to keep the strength of the electrode pad (device-side external electrode portion) 4 and decrease the influence by a thermal stress of the electrode (through-hole electrode portion) 6.

### Embodiment 2

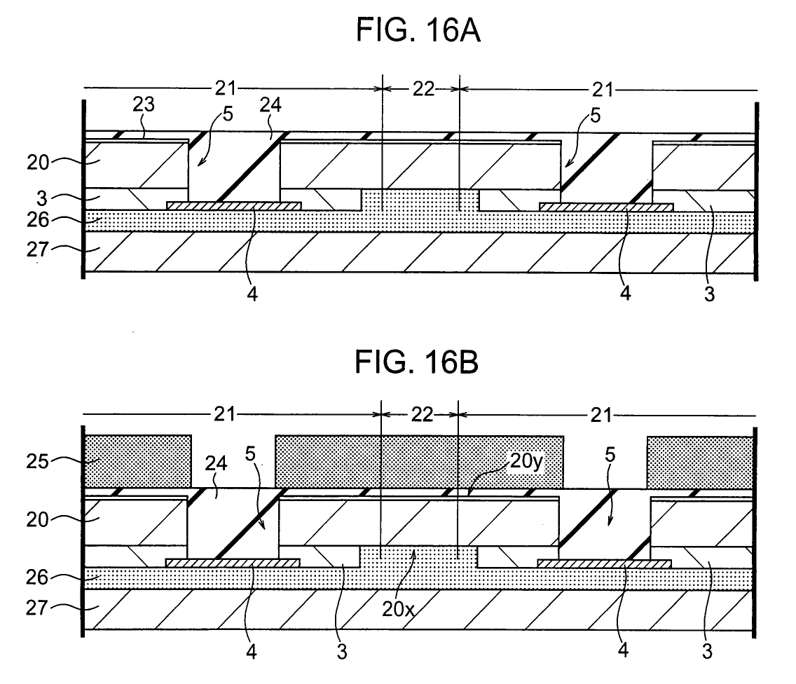

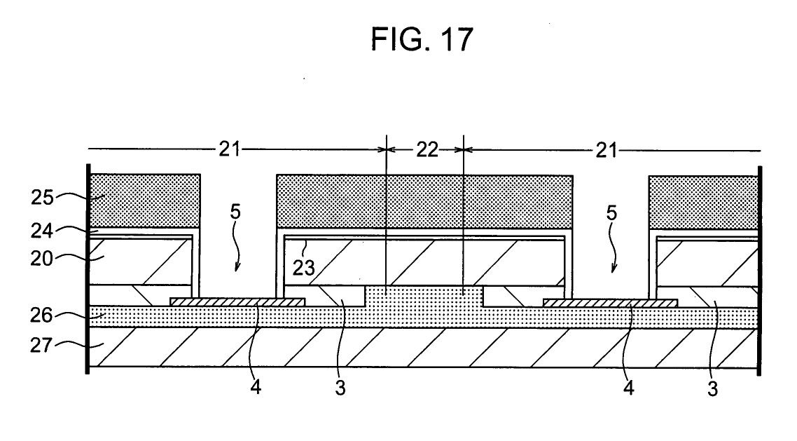

FIGS. 16 and 17 are schematic sectional views for explaining fabrication of a semiconductor chip in fabrication of a semiconductor device of embodiment 2 of the present invention.

As a method for covering the inner wall surface of a through-hole 5 with an insulating film 24, an example is described in which the inner-wall surface of the through-hole 5 is covered with the insulating film 24 by forming the thin insulating film 24 along the inner-wall surface of the through-hole 5 in the case of the above embodiment 1. In the case of this embodiment 2, an example is described in which the inside of the through-hole 5 is once filled with an insulating film 5 to cover the inner-wall surface of the through-hole 5 with the insulating film 24.

First, after forming the through-hole 5, the insulating film 24 made of a silicon oxide film is formed on the entire surface of the back 20y of a semiconductor wafer 20 through, for example, the plasma CVD method as shown in FIG. 16A.

Then, as shown in FIG. 16B, a mask 25 made of a photoresist film is formed on the back 20y of the semiconductor wafer 20. The mask 25 has an opening on the through-hole 5 and the inside diameter of the opening is smaller than the inside diameter of the through-hole 5 so that at least the insulating film 24 is left on the inner-wall surface of the through-hole 5.

Then, the insulating film 24 in the through-hole 5 is selectively etched by using the mask 25 as an etching mask. Thereby, as shown in FIG. 17, the inner-wall surface of the through-hole 5 is covered with the thin insulating film 24 and the back of an electrode pad 4 is exposed. Thereafter, an electrode 6 is formed in accordance with the same method as the case of the embodiment 1.

Thus, also in the case of this embodiment 2, it is possible to insulate and separate the electrode 6 from the semiconductor wafer 20 (semiconductor substrate 2) similarly to the case of the above embodiment 1.

### Embodiment 3

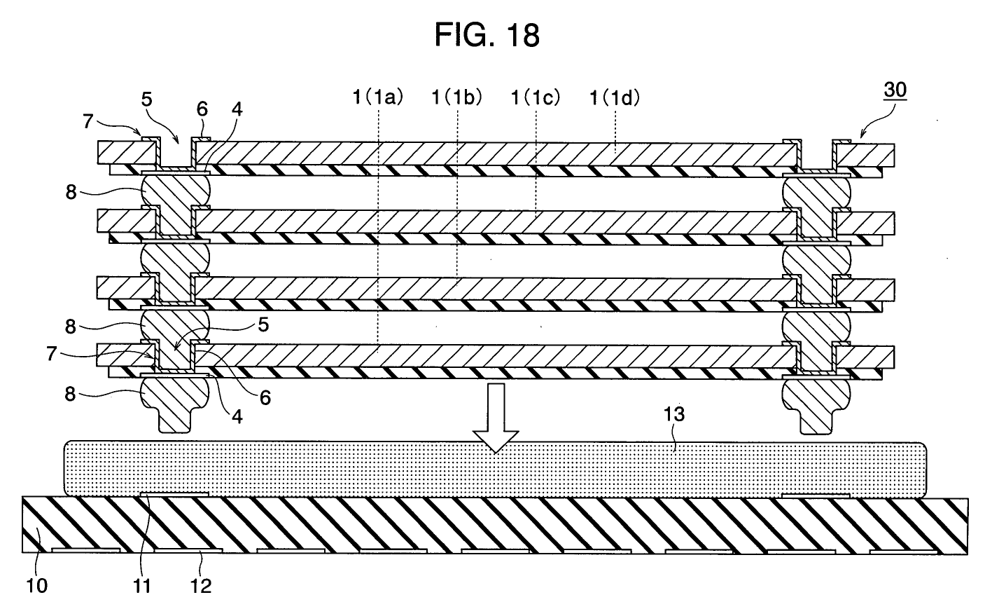

FIG. 18 is a schematic sectional view for explaining an assembling process in fabrication of a semiconductor device of embodiment 3 of the present invention.

In the case of the above embodiment 1, an example is described in which the lowest-stage semiconductor chip 1 (1a) is mounted on the principal plane of the wiring board 10 through the adhesive 13 and then three semiconductor chips (1b, 1c, and 1d) are successively laminated on the lowest-stage semiconductor chip (1a) to form the chip lamination body 30. Thereafter, the chip lamination body 30 is mounted on the principal plane of the wiring board 10. The chip lamination body 30 is mounted by compression-bonding the chip lamination body 30 to the wiring board 10 while setting the adhesive 13 between the semiconductor chip 1 (1a) and the wiring board 10.

Also in the case of this embodiment 3, advantages same as those of the above embodiment 1 are obtained.

### Embodiment 4

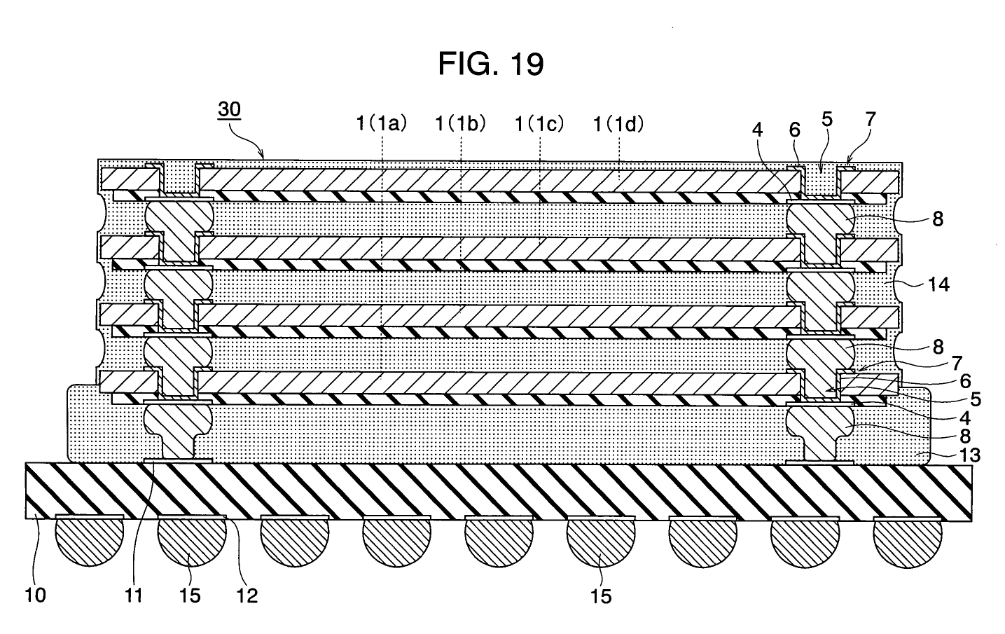

FIG. 19 is a schematic sectional view showing a schematic configuration of a semiconductor device of embodiment 4 of the present invention.

The above embodiment 1 has a structure in which the electrode 6 of the highest-stage semiconductor chip 1 (1d) is exposed. However, as shown in FIG. 19, the semiconductor device of this embodiment 4 has a structure in which a highest-stage semiconductor chip 1 (1d) has an electrode 6 covered by a sealing adhesive 14. By using this structure, it is possible to improve the reliability of the semiconductor device.

### Embodiment 5

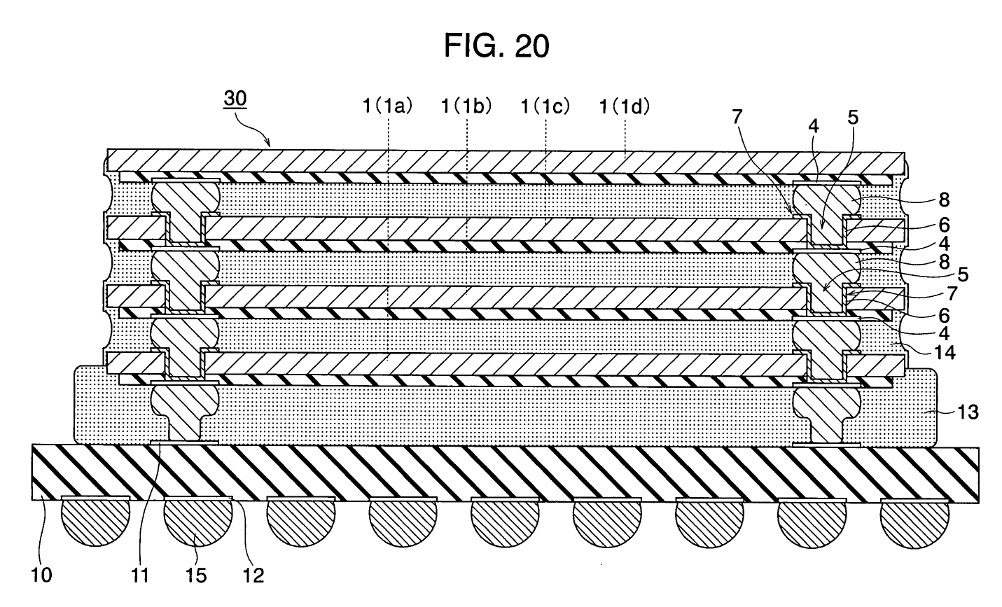

FIG. 20 is a schematic sectional view showing a schematic configuration of a semiconductor device of embodiment 5 of the present invention.

As shown in FIG. 20, the semiconductor device of this embodiment 5 has a structure in which a semiconductor chip 1 (1d) located at the highest stage is different from other semiconductor chips 1 (1a, 1b, and 1c). That is, though a through-hole 5 and an electrode 6 are provided for the semiconductor chips 1 (1a, 1b, and 1c), the through-hole 5 or electrode 6 is not provided for the highest-stage semiconductor chip 1 (1d). By using the above structure, it is possible to improve the reliability of a semiconductor device also in this embodiment 5.

### Embodiment 6

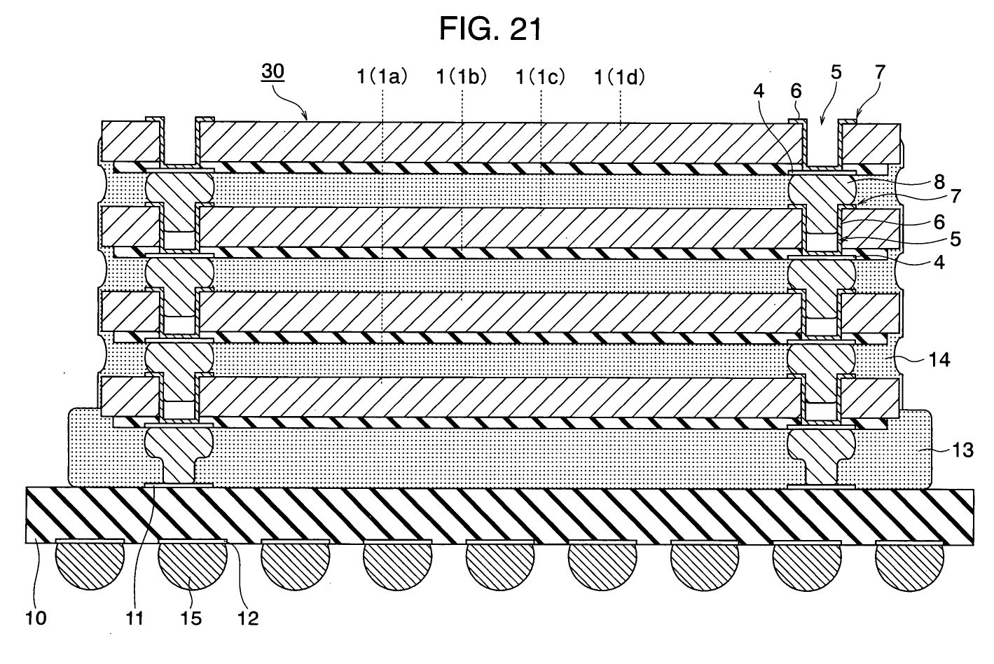

FIG. 21 is a schematic sectional view showing a schematic configuration of a semiconductor device of embodiment 6 of the present invention.

The embodiment 6 has a basic structure and its purpose same as those of the embodiment 1. However, the embodiment 6 shows an embodiment when the thickness of a semiconductor chip 1 having a through-hole electrode 7 is large compare to the case of the embodiment 1. A stud bump 8 compression-bonded and injected into the hole (concave portion) of the electrode (through-hole electrode) 6 is mechanically contacted or joined with only a back-side electrode portion and the sidewall electrode portion in the hole but it is not directly connected with the device-side electrode portion (bottom portion) in a through-hole, that is, an electrode pad 4. In this case, because the front end of the stud bump 8 does not reach the bottom portion in the trough-hole when the stud bump 8 is compression-bonded and injected, it is impossible to expect an effect that a metallic bump is re-deformed due to plastic flow at the bottom portion and expands in the circumferential direction. Therefore, it is preferable that a hole formed through dry etching is so that the hole diameter is equal or becomes slightly narrow to the depth direction differently from the hole shape shown in FIGS. 4 and 15 and the hole is formed into a shape titling by several degrees inward from a vertical line. Thereby, it is possible to realize a stable connection state with the sidewall portion in the through-hole when the stud bump 8 is compression-bonded and injected. Or when the hole depth reaches the same level as the case of the embodiment 1 by growing only the bottom portion (contact region with device-side external electrode) of an electrolytic plating film formed in the hole, it is allowed that the hole is formed into the hole shape shown in FIGS. 4 and 15.

### Embodiment 7

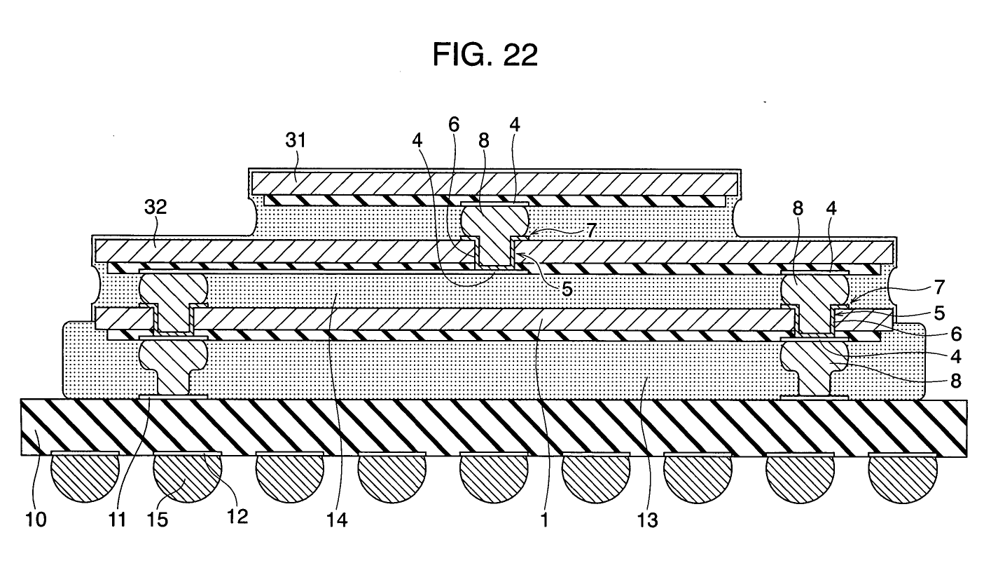

FIG. 22 is a schematic sectional view showing a schematic configuration of a semiconductor device of embodiment 7 of the present invention.

This embodiment 7 shows an embodiment in which different types of semiconductor chips are three-dimensionally laminated in accordance with the embodiment 1. In the case of a lowest-stage semiconductor chip 1 in which an electrode (through-hole electrode portion) 6 is formed on the back-1y side, a stud bump 8 is formed on an electrode pad (device-side external electrode portion) 4 and electrically connected to a wiring board (mounting substrate or package substrate) 10 through the stud bump 8. Electrical connection between the lowest-stage semiconductor chip 1 and a different type of highest-stage semiconductor chip 31 is realized by laminating an interposer substrate 32 made of Si for re-wiring between the lowest-stage semiconductor chip 1 and the highest-stage semiconductor chip 31. The stud bump 8 is formed at a position corresponding to the electrode 6 of the lowest-stage semiconductor chip 1 on the interposer substrate 32 and the electrode (through-hole electrode portion) 6 same as the case of the embodiments 1 and 2 is formed at a position corresponding to the stud bump 8 of the highest-stage semiconductor chip 1. The stud bump 8 and the electrode 6 are electrically connected by a wiring formed on the interposer substrate 32 and the lowest-stage semiconductor chip 1 and the highest-stage different type of the semiconductor chip 31 are electrically three-dimensionally connected by a shortest wiring length. It is a matter of course that it is possible not only to form a wiring pattern for re-wiring but also to constitute a wiring pattern considering high-speed signal transmission such as a wiring design for matching a characteristic impedance by forming a capacitor. For example, the lowest-stage semiconductor chip 1 is a high-performance microcomputer (MPU) having a frequency performance in a gigahertz band. When the highest-stage semiconductor chip 31 is a high-speed memory (DRAM: Dynamic Random Access Memory), it is possible to form a high-speed-bus transmission design between the MPU and the DRAM on the intermediate Si interposer 32 at a high density and shortest wiring length and construct a high-performance system substituted for a system LSI constituted of an SOC (System On Chip) process mixed-loading a large-capacity memory. Because a long-distance inter-chip connection such as board mounting is normally premised, a signal driving capacity is improved even if sacrificing the high-speed low-power characteristic of the input/output circuit of each chip. However, by realizing the above shortest-wiring-length inter-chip connection, it is possible to set an input/output-circuit driving capacity to a small value equivalent to an SOC and accelerate high-speed transmission and lower power consumption of a device. Moreover, when mixed-loading a memory such as an SRAM, the heat resistant temperature of the memory is low compared to a general device. Therefore, it is possible to provide a function for not easily transferring the heat generated by a high-performance microcomputer (MPU) to the memory side for the Si interposer substrate. For example, a material having a heat conductivity lower than that of a normal epoxy resin is used for a resin for sealing the gap between the microcomputer and the Si interposer substrate. Moreover, there is means for coating the surface of an Si interposer with a material having a low heat conductivity.

### Embodiment 8

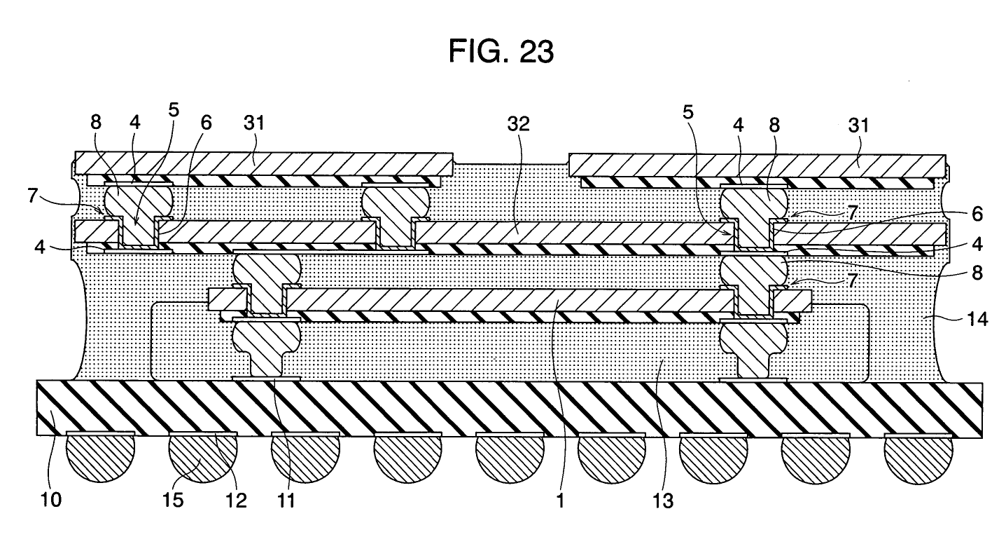

FIG. 23 is a schematic sectional view showing a schematic configuration of a semiconductor device of embodiment 8 of the present invention.

The embodiment 8 shows an embodiment in which two different types of semiconductor chips are mixed-laminated on an interposer substrate 32 made of Si in the embodiment 7. For example, similarly to the embodiment 7, the embodiment 8 is a system in which a lowest-stage chip 1 is a high-performance microcomputer (MPU) having a frequency characteristic in a gigahertz band, a high-speed memory (DRAM) and a flash memory (Flash) are mixed-mounted on a highest-stage chip 31, and the MPU, DRAM, and Flash are electrically connected at a shortest wiring length through a through-hole electrode 7. Similarly to the embodiment 7, it is unnecessary to form an electrode (through-hole electrode 7) 6 on the highest-layer DRAM and Flash and thickness is not restricted. Therefore, it is easy to purchase a chip from the outside and construct a system.

### Embodiment 9

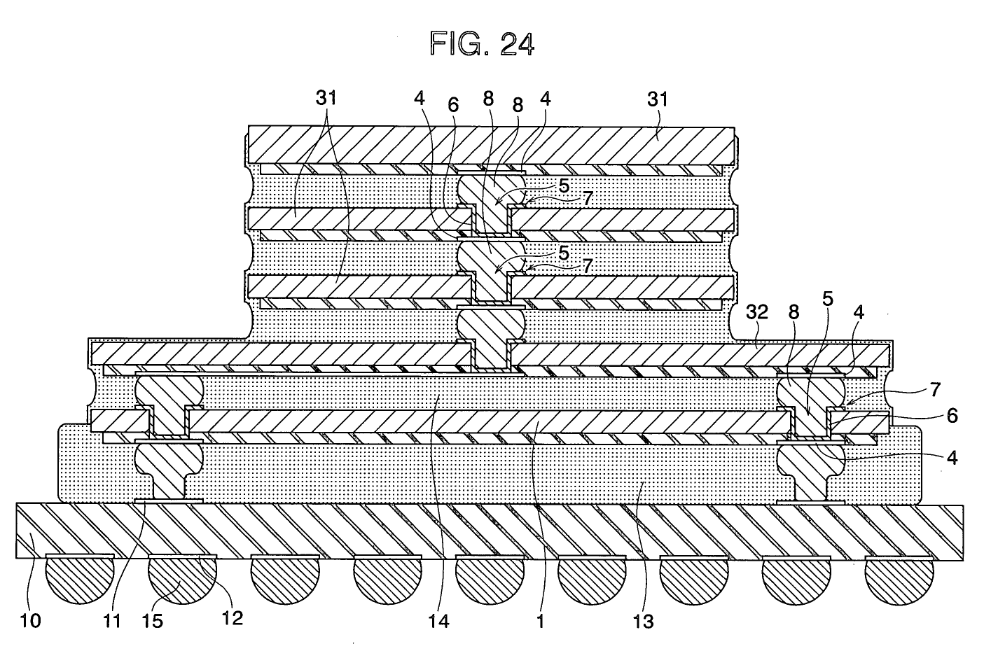

FIG. 24 is a schematic sectional view showing a schematic configuration of a semiconductor device of embodiment 9 of the present invention.

The embodiment 9 shows a case in which a lot of the upper-stage semiconductor chips 31 are laminated through the interposer substrate 32 made of Si in the embodiment 7. For example, when a DRAM is used for the upper-stage semiconductor chip 31, it is possible to realize a high-speed and large-capacity memory-mounted microcontroller (MPU) system through an SOC in the case of this embodiment 9. Moreover, by multistage-laminating memories in an old-generation process, it is also possible to construct a low-cost and high-yield system while increasing the capacity.

### Embodiment 10

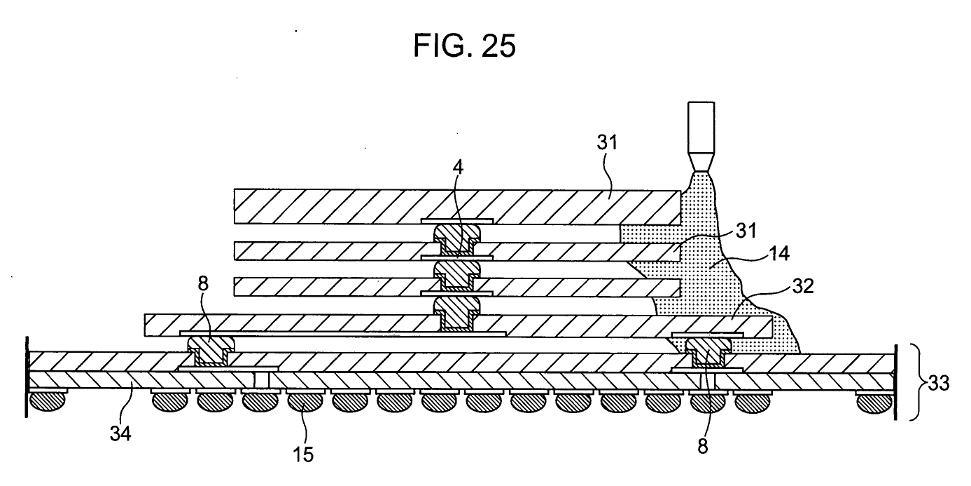

FIG. 25 is a schematic sectional view showing fabrication of a semiconductor device of embodiment 10 of the present invention.

In the case of this embodiment 10, an electrode (through-hole electrode 7) 6 same as the case of 9 is formed from the embodiment 1 at a position corresponding to a device-side external electrode on a lowest-stage semiconductor chip 33. The device side is different from the case of 9. That is, the embodiment 10 is not electrically connected to a wiring board (mounting substrate or package substrate) through a stud bump 8. Re-wiring from the external electrode portion, insulating film (polyimide film) formation, and external electrode (solder bump) formation are executed on a wafer process. That is, a lowest-stage semiconductor chip 33 is packaged while it is in a wafer state by applying a packaging technique generally referred to as WPP (Wafer Process Package). The lowest-stage semiconductor chip 33 is electrically connected into the hole (concave portion) of the electrode 6 formed on the back side while it is in a wafer state before it is diced into pieces when the stud bump 8 formed on the electrode pad (external electrode) 4 of a semiconductor chip 31 laminated at the upper stage side is deformed and injected. It is allowed that a plurality of semiconductor chips 31 are laminated and mounted at a wafer level in accordance with the above method and finally chip laminating areas are sealed by using the adhesive 14 such as UNDER-FILL or the whole wafer is simultaneously sealed by using transfer mold resin. Finally the wafer is diced into pieces and the packaging process is completed. In the case of this embodiment 10, as in the embodiment 7, for example, the lowest-stage semiconductor chip 33 constituted of a WPP is a high-performance microcomputer (MPU) having a frequency performance in a gigahertz band, the highest-stage semiconductor chip 31 is a high-speed memory (DRAM), and it is possible to form high-speed bus transmission between the MPU and the DRAM at a high density and a shortest wiring length on an intermediate Si interposer 32. However, because of lamination mounting at a wafer level, when a lowest-stage semiconductor chip is smaller than an upper-stage semiconductor chip in chip size, the upper-stage semiconductor chip cannot be mounted. In this case, by constituting a semiconductor chip having the smallest chip size or the Si interposer substrate 32 by a lowest-stage WPP, lamination mounting at a wafer level can be made.

### Embodiment 11

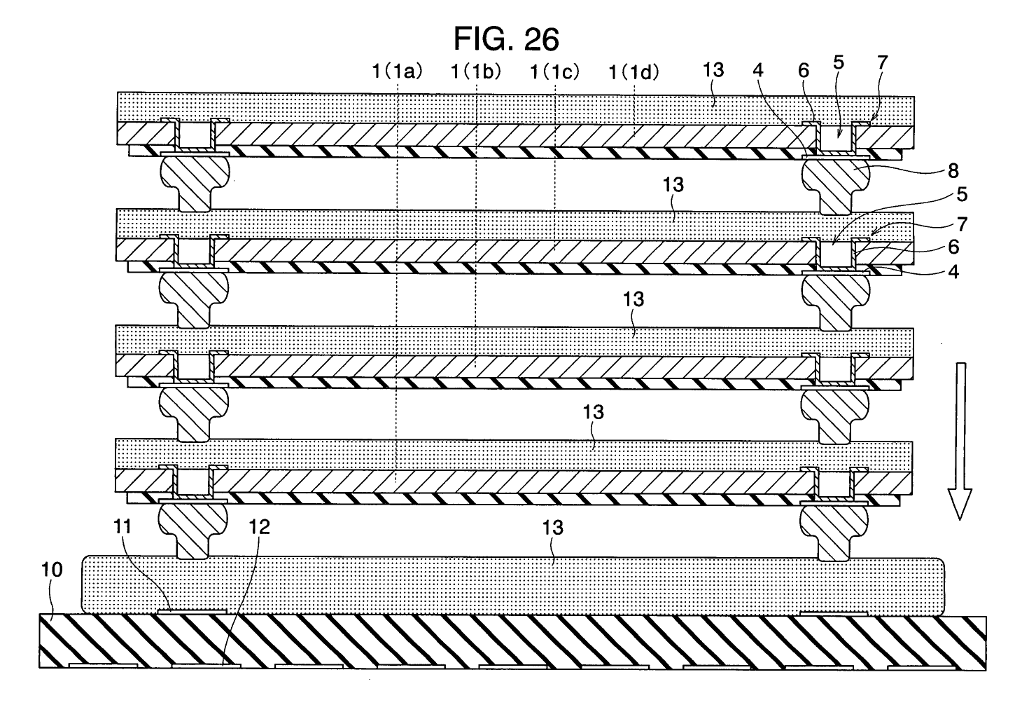

FIG. 26 is a schematic sectional view showing a method for connecting upper and lower semiconductor chips in fabrication of a semiconductor device of embodiment 11 of the present invention.

An electrode 6 is formed in accordance with fabrication processes shown in FIGS. 4 and 15 and then, sheet-like adhesive 13 is entirely attached to the side on which the electrode (back through-hole electrode) 6 is formed while it is in a wafer state and diced into individual semiconductor chip 1 while the adhesive 13 is attached. Each semiconductor chip 1 is stored in a chip tray while the adhesive 13 is attached to the back of the semiconductor chip 1. A state is also allowed in which the adhesive 13 is attached to the device circuit face side while it is in a wafer state. However, because there is a case in which recognition of an alignment mark for alignment when mounting semiconductor chips may be made difficult, the adhesive is restricted to an adhesive having a high transparency. A wiring board 10 on which semiconductor chips 1 are mounted is fabricated in a configuration in which a plurality of semiconductor chips 1 can be mounted on an area array and the same adhesive 13 is previously attached to each chip mounting area. As illustrated, each semiconductor chip 1 on whose back adhesive is attached is laminated at multistage while alignment between the electrode (back electrode portion) 6 formed on a lower-stage semiconductor chip and a stud bump 8 formed on an upper-stage semiconductor chip is executed. By aligning the highest-stage semiconductor chip 1 and applying compression bonding load of ultrasonic waves when laminating the highest-stage semiconductor chip 1, all chips are simultaneously connected. In the case of the embodiment 6, because the inside of the hole of the electrode 6 is deeper than the case of the embodiment 1, a part of the adhesive 13 is injected into the electrode 6 and an effect for filling the gap with the compression-bonded and injected stud bump 8 is expected. In the case of the embodiment 6, an example using an adhesive such as UNDER-FILL is described. However, according to this method, because a sealing process after connection between chips is completed is unnecessary, the process can be simplified. However, when a moisture resistance is required, it is also allowed that the whole chip mounting area is re-sealed by transfer mold resin according to necessity.

### Embodiment 12

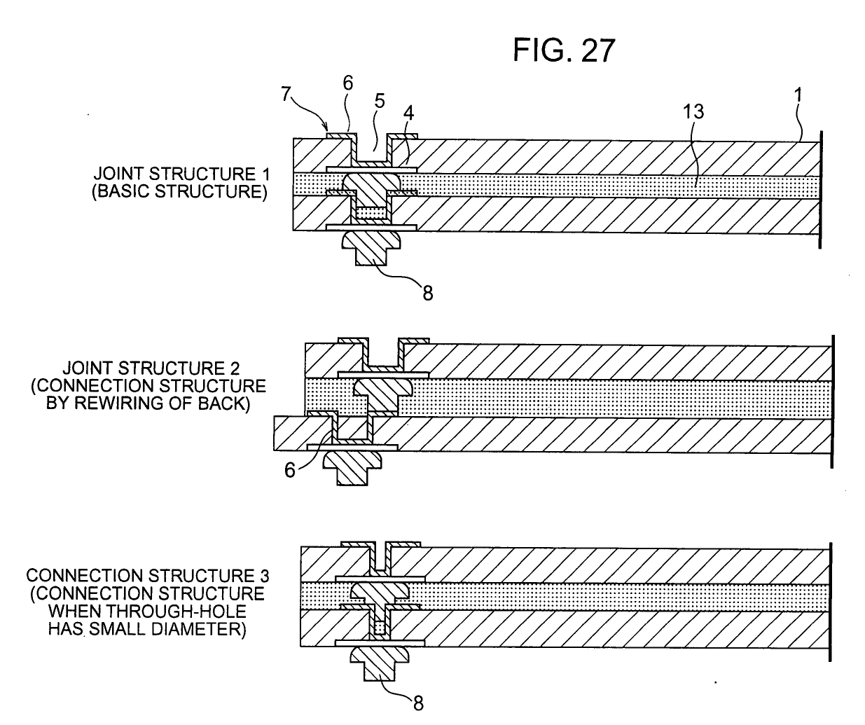

FIG. 27 shows a structure for bump-connection between lower-stage and upper-stage semiconductor chips.

A basic inter-chip connection structure by the present invention is a connection structure 1 shown on the highest stage, which is a joint structure in which a stud bump 8 formed on the upper-stage semiconductor chip is compression-bonded and injected into the hole of an electrode 6 formed on the back of the lower-stage semiconductor chip and a geometric caulking state is formed. However, a case is estimated in which it is difficult to make the electrode position on the back of the lower-stage semiconductor chip coincide with the stud bump position of the upper-stage semiconductor chip from a design restriction. In this case, as shown by the joint structure 2 at the middle stage in FIG. 27, it is allowed to form a re-wiring area on the electrode side of the back, thereby correct the shift between the upper- and lower-stage semiconductor chips, and connect the upper- and lower-stage semiconductor chips. Moreover, when it is impossible to sufficiently secure the hole diameter of the electrode on the back from the design restriction, it is possible to connect the chips by compression-bonding and injecting a metallic bump into the hole of a through-hole electrode smaller than the size of the metallic bump as shown by the lowest-stage joint structure 3.

### Embodiment 13

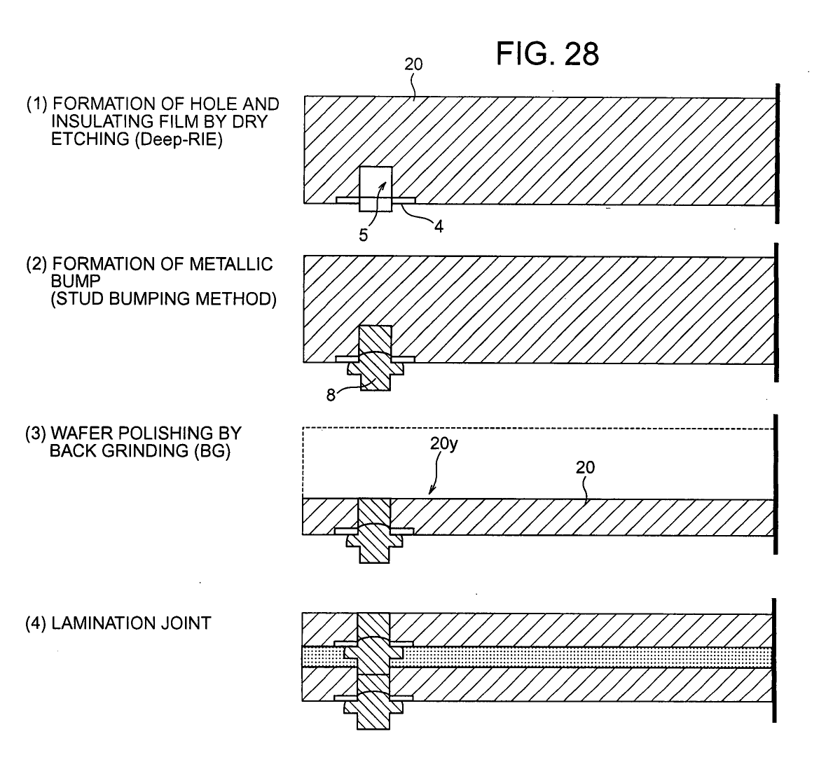

FIG. 28 is a schematic sectional view sowing a fabrication process of a semiconductor chip in fabrication of a semiconductor device of embodiment 13 of the present invention.

(1) A plurality of holes are formed in a wafer on a device-side external electrode portion or at a position adjacent to the electrode in a wafer state through dry etching (Deep-RIE) and an oxide insulating film is formed on the sidewall of the hole through plasma CVD (Chemical Vapor Deposition) or the like.

(2) An Au stud bump is formed through the stud bumping method. A bump by the first-time bumping is injected into a hole and a bump bumped at the second time is formed as an external electrode.

(3) A silicon wafer ground through back grinding (BG) up to the position of the bump injected into the above hole. When metallic bump components are distributed in the wafer surface, simple etching and cleaning are executed.

(4) The stud bump (metallic bump) of an upper-stage semiconductor chip is deformed and injected into a hole while deforming a penetration bump area on the back side of a lower-stage semiconductor chip downward when a compression load (and ultrasonic waves) is applied to the bump from the outside and upper and lower chips are electrically connected each other. In the case of this embodiment, the cost of a process can be decreased because a plating process is unnecessary.

Inventions made by the present inventor are specifically described above in accordance with the embodiments. However, the present invention is not restricted to the embodiments. It is a matter of course that various modifications are allowed as long as the modifications are not deviated from the gist of the present invention.

It should be further understood by those skilled in the art that although the foregoing description has been made on embodiments of the invention, the invention is not limited thereto and various changes and modifications may be made without departing from the spirit of the invention and the scope of the appended claims.

1. A semiconductor device comprising a first semiconductor chip and a second semiconductor chip laminated on the first semiconductor chip; wherein
the first semiconductor chip has a principal plane and a back located at the opposite side each other, a first electrode set to the principal plane, a through-hole reaching the first electrode from the back, and a second electrode formed along the inner wall surface of the through-hole and electrically connected with the first electrode,
the second semiconductor chip has a principal plane and a back at the opposite side each other, a first electrode set to the principal plane, and a protruded electrode set on the first electrode and protruded from the principal plane, and
a part of the protruded electrode of the second semiconductor chip is inserted into the through-hole through the second electrode of the first semiconductor chip and electrically connected with the first electrode of the first electrode of the first semiconductor chip.

2. The semiconductor device according to claim 1, wherein
the second electrode is constituted of a metallic deposit.

3. The semiconductor device according to claim 1, wherein
a part of the protruded electrode of the second semiconductor chip compression-bonded and injected due to a deformation followed by plastic flow.

4. The semiconductor device according to claim 1, wherein
at least a part of the inside diameter of the protruded electrode is formed so as to be widened to the depth direction, and
a part of the protruded electrode is compression-bonded and injected due to a deformation followed by plastic flow to become a geometric caulking state.

5. The semiconductor device according to claim 1, wherein
the protruded electrode is an Au stud bump or Au plated bump, and
the second electrode is constituted of a Cu metallic deposit or Au metallic deposit.

6. The semiconductor device according to claim 1, further comprising:
the second semiconductor chip having a through-hole reaching a first electrode of the second semiconductor chip from the back of the second semiconductor chip and a second electrode formed along the inner wall surface of the through-hole and electrically connected with the first electrode.

7. The semiconductor device according to claim 1, wherein
the first semiconductor chip is mounted on a wiring board through a protruded electrode.

8. The semiconductor device according to claim 1, wherein
storage circuits having the same function are mounted on the first and second semiconductor chips.

9. A semiconductor device comprising a first semiconductor chip and a second semiconductor chip laminated on the first semiconductor chip through an interposer substrate, wherein
the first semiconductor chip has a principal plane and a back located at the opposite side each other, a first electrode set to the principal plane, a through-hole reaching the first electrode from the back, and a second electrode formed along the inner wall surface of the through-hole and electrically connected with the first electrode,
the second semiconductor chip has a principal plane and a back located at an opposite position each other, a first electrode set to the principal plane, and a protruded electrode set on the first electrode and protruded from the principal plane,
the interposer substrate has a principal plane and a back located at the opposite side each other, a first electrode set to the principal plane, a protruded electrode set on the first electrode and protruded from the principal plane, a through-hole extending toward the principal plane from the back, and a second electrode formed along the inner wall surface of the through-hole and electrically connected with the first electrode,
a part of the protruded electrode of the interposer substrate compression-bonded and injected into the through-hole of the first semiconductor chip through a second electrode of the first semiconductor chip by a deformation followed by plastic flow and electrically connected with the first electrode of the first semiconductor chip, and
a part of the protruded electrode of the second semiconductor chip is compression-bonded and injected into the through-hole of the interposer substrate through the second electrode of the interposer substrate due to a deformation followed by plastic flow and electrically connected with the second electrode of the interposer.

10. The semiconductor device according to claim 9, wherein
a microcomputer or a logic circuit is mounted on the first semiconductor chip and a storage circuit is mounted on the second semiconductor chip.

11. A semiconductor device fabrication method using a first semiconductor chip having a first electrode set to a principal plane, a through-hole reaching the first electrode from a back at the opposite side to the principal plane, and a second electrode electrically connected with the first electrode, comprising:
a step of preparing a semiconductor chip having a first electrode set to the principal plane and a protruded electrode set on the first electrode and protruded from the principal plane; and
a step of compression-bonding and injecting a part of the protruded electrode of the first semiconductor chip into the through-hole of the first semiconductor chip through the second electrode of the first semiconductor chip due to a deformation followed by plastic flow.

12. A semiconductor device fabrication method using a first semiconductor chip having a first electrode set to a principal plane, a through-hole reaching the first electrode from the back opposite side to the principal plane, and a second electrode formed along the inner wall surface of the through-hole and electrically connected with the first electrode and a second semiconductor chip having a first electrode set to a principal plane and a protruded electrode set on the first electrode and protruded from the principal plane, comprising:
a step of preparing an interposer substrate having a first electrode set to a principal plane, a protruded electrode set on the first electrode and protruded from the principal plane, a through-hole extending toward the principal plane from the back opposite side to the principal plane, and a second electrode formed along the inner wall surface of the through-hole and electrically connected with the first electrode;
a step of compression-bonding and injecting the second electrode of the interposer substrate into the through-hole of the first semiconductor chip through the second electrode of the first semiconductor chip; and
a step of compression-bonding and injecting a part of the protruded electrode of the second semiconductor chip into the through-hole of the interposer substrate through the second electrode of the interposer substrate in accordance with a deformation followed by plastic flow.
